(19) United States
(12) Patent Application Publication
(10) Pub. No.: US 2019/0180671 A1
(43) Pub. Date: Jun. 13, 2019

(54) GATE DRIVER CIRCUIT

(71) Applicant: Chunghwa Picture Tubes, LTD., Taoyuan City (TW)

(72) Inventors: Po-Sheng Cheng, Kaohsiung City (TW); Jhen-Shen Liao, Taoyuan City (TW); Chien-Hsun Kuan, Taoyuan City (TW)

(73) Assignee: Chunghwa Picture Tubes, LTD., Taoyuan City (TW)

(21) Appl. No.: 15/968,765

(22) Filed: May 2, 2018

(30) Foreign Application Priority Data
Dec. 12, 2017 (CN) 201711314919.8

(51) Int. Cl. G09G 3/20; G11C 19/28

(52) U.S. Cl. CPC G09G 3/2092; G11C 19/28; G09G 2310/0286; G09G 2310/0283; G09G 2310/0297; G09G 2310/06; G09G 2320/0204

(57) ABSTRACT

A gate driver circuit is provided. The gate driver circuit includes a plurality of gate driver units. The gate driver units are coupled to each other in sequence, and each of the gate driver units includes a shift register and a de-multiplexer. The shift register receives one of a plurality of operation clock signals and a startup signal and generates a first control signal and a second control signal according to the startup signal and the received operation clock signal. The de-multiplexer is coupled to the shift register and receives a portion of a plurality of gate clock signals to output the received portion of the gate clock signals according to the first control signal to generate a plurality of gate signals in sequence. The gate clock signals are enabled in sequence, and enabling durations of two consecutive clock signals in the gate clock signals are partially overlapped.

### CROSS-REFERENCE TO RELATED APPLICATION

This application claims the priority benefit of China application serial no. 201711314919.8, filed on Dec. 12, 2017. The entirety of the above-mentioned patent application is hereby incorporated by reference herein and made a part of this specification.

### BACKGROUND OF THE INVENTION

### 1. Field of the Invention

The invention relates to a gate driver circuit.

### 2. Description of Related Art

Thanks to advancement in optoelectronic and semiconductor technologies, the flat displays have become widely applied in recent years. A gate in panel (GIP) technology has gradually developed currently in order to achieve cost reduction and meet the design requirement of narrow border. Nevertheless, display panels are required to provide high resolution in existing trends, the resistive-capacitive loading of the conductive lines disposed at the peripheral circuit areas is inevitably increased. It is thus difficult for the gate driver circuits to provide driving voltages large enough to drive the display panels.

Therefore, how to provide sufficient driving capability, meet the design requirement of narrow border, and deliver high resolution are important goals for the researchers in this field.

### SUMMARY OF THE INVENTION

The invention relates to a gate driver circuit which may suppress a noise of a gate driver unit so as to provide favorable driving capability, deliver high resolution, and meet design requirement of narrow border.

In an embodiment of the invention, a gate driver circuit includes a plurality of gate driver units. The gate driver units are coupled to each other in sequence, and each of the gate driver units includes a shift register and a de-multiplexer. The shift register receives one of a plurality of operation clock signals and a startup signal and generates a first control signal and a second control signal according to the startup signal and the received operation clock signal. The de-multiplexer is coupled to the shift register and receives a portion of a plurality of gate clock signals to output the received portion of the gate clock signals according to the first control signal to generate a plurality of gate signals in sequence. The gate clock signals are enabled in sequence, and enabling durations of two consecutive clock signals in the gate clock signals are partially overlapped.

To sum up, in the gate driver circuit of the embodiments of the invention, one shift register corresponds to plural de-multiplexers to control the de-multiplexers to output the gate signals. Moreover, the anti-noise unit in the shift register may ensure that the first internal voltage, the first control signal, and the gate signals are not in the floating state when the gate driver unit is in the non-operational period. Therefore, in the gate driver unit, output stability may be enhanced and erroneous output may be less likely to occur.

To make the aforementioned and other features and advantages of the invention more comprehensible, several embodiments accompanied with drawings are described in detail as follows.

### BRIEF DESCRIPTION OF THE DRAWINGS

FIG. 1A is a schematic diagram of a system of a display panel according to an embodiment of the invention.

FIG. 1B is a schematic diagram of a system of a gate driver circuit according to an embodiment of the invention.

FIG. 2A is a schematic diagram of a circuit of a gate driver unit according to a first embodiment of the invention.

FIG. 2B is a schematic diagram of driving waveforms of the gate driver units according to the first embodiment of the invention.

FIG. 3A is a schematic diagram of a circuit of a gate driver unit according to a second embodiment of the invention.

FIG. 3B is a schematic diagram of driving waveforms of the gate driver units according to the second embodiment of the invention.

FIG. 4A is a schematic diagram of a circuit of a gate driver unit according to a third embodiment of the invention.

FIG. 4B is a schematic diagram of driving waveforms of the gate driver units according to the third embodiment of the invention.

### DESCRIPTION OF THE EMBODIMENTS

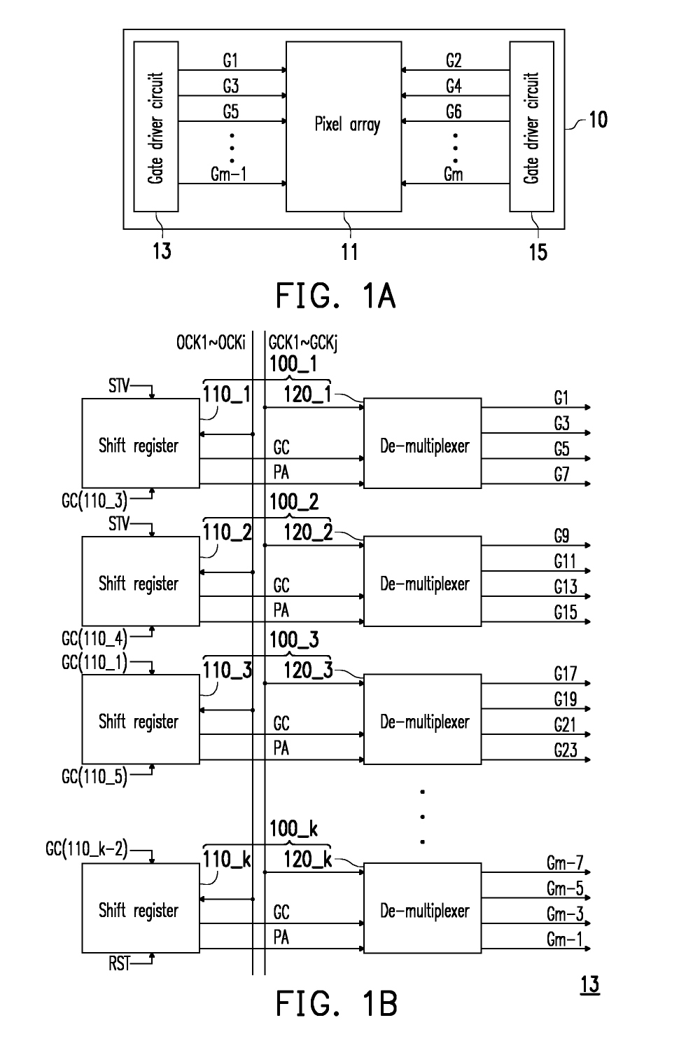

FIG. 1A is a schematic diagram of a system of a display panel according to an embodiment of the invention. With reference to FIG. 1A, in this embodiment, a display panel 10 includes a pixel array 11 and gate driver circuits 13 and 15, wherein a plurality of pixels (not shown) arranged in an array may be disposed in the pixel array 11, but the invention is not limited to the above. The gate driver circuits 13 and 15 are disposed at two opposite sides of the pixel array 11, so as to respectively provide gate signals G1 to Gm required for driving the pixel array 11. The gate driver circuit 13 provides, for example, the odd gate signals G1, G3, . . . , Gm-1, the gate driver circuit 15 provides, for example, the even gate signals G2, G4, . . . , Gm, and m is a row number of the pixel array 11.

FIG. 1B is a schematic diagram of a system of a gate driver circuit according to an embodiment of the invention. With reference to FIG. 1 A and FIG. 1B, identical or similar components are assigned with identical or similar reference numerals. The gate driver circuit 13 is taken as an example herein, and a circuit structure of the gate driver circuit 15 is similar to a circuit structure of the gate driver circuit 13. In this embodiment, the gate driver circuit 13 includes a plurality of gate driver units 100_1 to 100_k, wherein k is a positive integer and is less than m. The gate driver units 100_1 to 100_k are coupled to each other in sequence to be triggered in sequence. Moreover, each of the gate driver units 100_1 to 100_k provides plural odd gate signals (e.g., G1, G3, . . . , Gm-1, etc.). m divided by a number of the odd gate signals (e.g., G1, G3, Gm-1, etc.) provided by each of the gate driver units 100_1 to 100_k equals k. Herein, each of the gate driver units 100_1 to 100_k provides 4 odd gate signals (e.g., G1, G3, . . . , Gm-1, etc.), but the invention is not limited to the above.

Each of the gate driver units 100_1 to 100_k respectively includes a shift register (e.g., 110_1 to 110_k) and a de-multiplexer (e.g., 120_1 to 120_k). The shift register (e.g., 110_1 to 110_k) of each of the gate driver units 100_1 to 100_k receives one of a plurality of operation clock signals OCK1 to OCKi and a startup signal and generates a first control signal GC and a second control signal PA according to the startup signal and the received operation clock signal (e.g., OCK1 to OCKi). The startup signal may be an initial signal STV or the first control signal GC provided by the shift register (e.g., 110_1 to 110_k) of the gate driver unit two stages before (e.g., 100_1 to 100_k), and i may be a positive integer. For instance, the startup signals of the shift registers 110_1 and 110_2 of the gate driver units 100_1 and 100_2 are the initial signals STV, and the startup signal of the shift register 110_3 of the gate driver unit 100_3 is the first control signal GC provided by the shift register 110_1.

The de-multiplexer (e.g., 120_1 to 120_k) of each of the gate driver units 100_1 to 100_k is coupled to the corresponding shift register (e.g., 110_1 to 110_k) and receives a portion of a plurality of gate clock signals GCK1 to GCKj (i.e., two or more gate clock signals GCK1 to GCKj), so as to output the received portion of the gate clock signals (e.g., GCK1 to GCKj) according to the corresponding first control signal GC to generate plural odd gate signals (e.g., G1, G3, . . . , Gm-1, etc.) in sequence. The gate clock signals (e.g., GCK1 to GCKj) are enabled in sequence and are different from the operation clock signals (e.g., OCK1 to OCKi), wherein enabling durations of two consecutive clock signals in the gate clock signals (e.g., GCK1 to GCKj) are partially overlapped, and j is a positive integer greater than i.

In addition, the shift register (e.g., 110_1 to 110_k) of each of the gate driver units 100_1 to 100_k may receive a turn-off signal to allow the shift register (e.g., 110_1 to 110_k) to stop providing the second signal PA. With reference to FIG. 1B, the turn-off signal may be a reset signal RST or the first control signal GC provided by the shift register (e.g., 110_1 to 110_k) of the gate driver unit two stages later (e.g., 100_1 to 100_k) in this embodiment.

Moreover, when the shift register (e.g., 110_1 to 110_k) of each of the gate driver units 100_1 to 100 k is activated, the first control signal GC provided by the activated shift register (e.g., 110_1 to 110_k) is related to the received operation clock signal (e.g., OCK1 to OCKi), and the second control signal PA is fixed to be a gate low voltage VGL. When the shift register (e.g., 110_1 to 110_k) of each of the gate driver units 100_1 to 100_k is turned off, the first control signal GC provided by the turned-off shift register (e.g., 110_1 to 110_k) is fixed to be the gate low voltage VGL, and the second control signal PA is related to the received operation clock signal (e.g., OCK1 to OCKi). In other words, in this embodiment, one of the first control signal GC and the second control signal PA provided by the shift register (e.g., 110_1 to 110_k) of each of the gate driver units 100_1 to 100_k is related to the received operation clock signal (e.g., OCK1 to OCKi), and the other one of the first control signal GC and the second control signal PA is fixed to be the gate low voltage VGL.

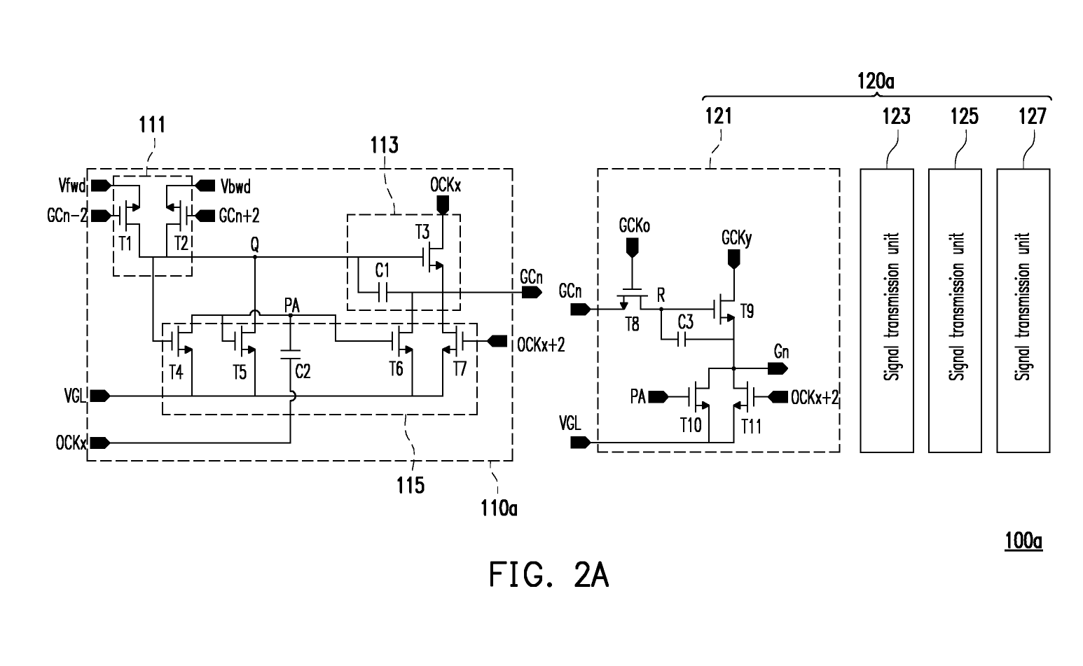

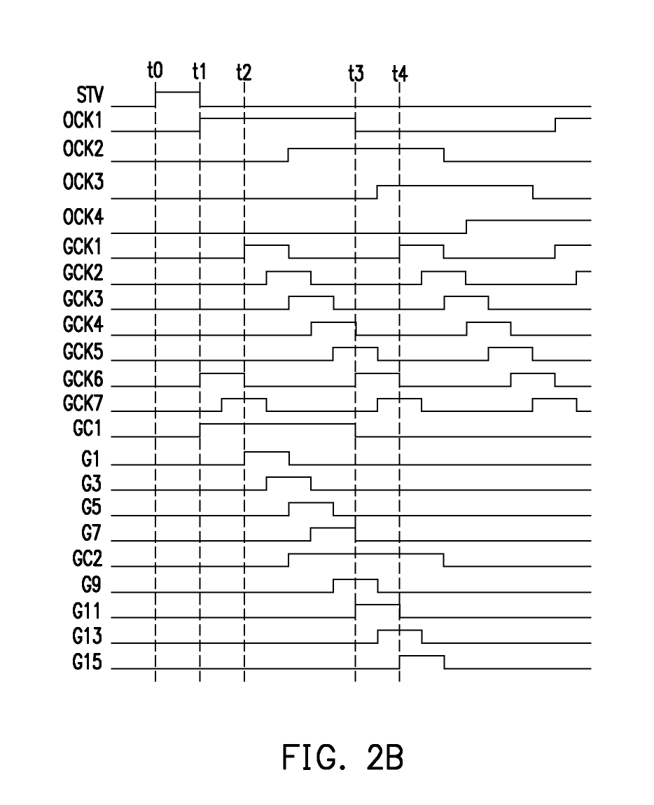

FIG. 2A is a schematic diagram of a circuit of a gate driver unit according to a first embodiment of the invention. With reference to FIG. 1A, FIG. 1B, and FIG. 2A, identical or similar components are assigned with identical or similar reference numerals. Moreover, the gate driver units (e.g., 100_1 to 100_k) may be implemented as a gate driver unit 100a, but the embodiments of the invention are not limited to the above. In this embodiment, the gate driver unit 100a includes a shift register 110a and a de-multiplexer 120a. The shift register 110a includes a voltage setting unit 111, a shift output unit 113, and an anti-noise unit 115.

The voltage setting unit 111 receives a forward scanning voltage Vfwd, a backward scanning voltage Vbwd, the corresponding initial signal (e.g., a first control signal GCn-2 two stages before), and the turn-off signal (e.g., a first control signal GCn+2 two stages later) to set a first internal voltage Q, wherein n is an index number. The shift output unit 113 receives the corresponding operation clock signal OCKx (i.e., one of the operation clock signals OCK1 to OCKi, and x is an index number) and the first internal voltage Q and determines whether to output the received operation clock signal OCKx according to the first internal voltage Q to provide the first control signal GC. The anti-noise unit 115 receives the first internal voltage Q and the first control signal GC to provide the second control signal PA according to the first internal voltage Q and pull down the first control signal GC according to the first internal voltage Q.

The de-multiplexer 120a includes a plurality of signal transmission units (4 signal transmission units 121, 123, 125, and 127 are taken as an example herein). The signal transmission units 121, 123, 125, and 127 respectively receive one of the portion of the continuity gate clock signals (e.g., the gate clock signal GCKy, wherein y is an index number) in the gate clock signals GCK1 to GCKj, the first control signal GC, and the second control signal PA, wherein the signal transmission units 121, 123, 125, and 127 are turned on simultaneously according to the first control signal PA. The signal transmission units 121, 123, 125, and 127 respectively provide the received clock signals (e.g., the gate clock signal GCKy) to respectively generate the gate signals (e.g., Gn). Moreover, the signal transmission units 121, 123, 125, and 127 are cut off simultaneously according to the second control signal PA. That is, the signal transmission units 121, 123, 125, and 127 have identical circuit structures but receive different gate clock signals (e.g., GCK1 to GCKj).

Further, the voltage setting unit 111 includes a first transistor Ti and a second transistor T2. The first transistor T1 has a first terminal receiving the forward scanning voltage Vfwd, a control terminal receiving the startup signal (e.g., the first control signal GCn-2 two stages before), and a second terminal receiving the first internal voltage Q. The second transistor T2 has a first terminal receiving the backward scanning voltage Vbwd, a control terminal receiving the turn-off signal (e.g., the first control signal GCn+2 two stages later), and a second terminal receiving the first internal voltage Q.

The shift output unit 113 includes a third transistor T3 and a first capacitor C1. The third transistor T3 has a first terminal receiving the operation clock signal OCKx, a control terminal receiving the first internal voltage Q, and a second terminal providing the first control signal GCn. The first capacitor C1 is coupled between the control terminal of the third transistor T3 and the second terminal of the third transistor T3.

The anti-noise unit 115 includes a fourth transistor T4, a fifth transistor T5, a sixth transistor T6, a seventh transistor T7, and a second capacitor C2. The fourth transistor T4 has a first terminal receiving the second control signal PA, a control terminal receiving the first internal voltage Q, and a second terminal receiving the gate low voltage VGL. The fifth transistor T5 has a first terminal receiving the first internal voltage Q, a control terminal receiving the second control signal PA, and a second terminal receiving the gate low voltage VGL. The sixth transistor T6 has a first terminal receiving the first control signal GC, a control terminal receiving the second control signal PA, and a second terminal receiving the gate low voltage VGL. The seventh transistor T7 has a first terminal receiving the first control signal GC, a control terminal receiving the operation clock signal two stages later of the operation clock signal OCKx received by the shift output unit 113, and a second terminal receiving the gate low voltage VGL. The second capacitor C2 is coupled between the operation clock signal OCKx and the second control signal PA.

The signal transmission unit 121 includes an eighth transistor T8, a ninth transistor T9, a tenth transistor T10, an eleventh transistor T11, and a capacitor C3. The eighth transistor T8 has a first terminal receiving the first control signal GC, a control terminal receiving one gate clock signal GCKo (corresponding to a charge control signal) of the gate clock signals GCK1 to GCKj not received by the de-multiplexer 120a, and a second terminal receiving a second internal voltage R, wherein o is an index number. The ninth transistor T9 has a first terminal receiving the gate clock signal GCKy, a control terminal receiving the second internal voltage R, and a second terminal providing the corresponding gate signal Gn. The third capacitor C3 is coupled between the control terminal of the ninth transistor T9 and the second terminal of the ninth transistor T9. The tenth transistor T10 has a first terminal receiving the corresponding gate signal Gn, a control terminal receiving the second control signal PA, and a second terminal receiving the gate low voltage VGL. The eleventh transistor T11 has a first terminal receiving the corresponding gate signal Gn, a control terminal receiving the operation clock signal OCKx+2 (corresponding to a pull-down control signal), and a second terminal receiving the gate low voltage VGL.

FIG. 2B is a schematic diagram of driving waveforms of the gate driver units according to the first embodiment of the invention. With reference to FIG. 2A and FIG. 2B, in this embodiment, 4 operation clock signals OCK1 to OCK4 are taken as an example, 7 gate clock signals GCK1 to GCK7 are taken as an example, and the startup signal is the initial signal STV. Herein, the operation clock signals OCK1 to OCK4 are signals having identical pulse widths but enabled in sequence, and enabling durations of the adjacent operation clock signals in the operation clock signals OCK1 to OCK4 are partially overlapped. Herein, the gate clock signals GCK1 to GCK7 are signals having identical pulse widths but enabled in sequence, and the enabling durations of the adjacent gate clock signals in the gate clock signals GCK1 to GCK7 are partially overlapped.

During a time period tO to a time period t1, the initial signal STV is enabled to turn on the first transistor Ti for charging the first internal voltage Q, and the operation clock signal OCK1 is at a low level at this time. Moreover, the third transistor T3 is turned on, so as to pull down the first control signal GC1 to the low level. Since the fourth transistor T4 is turned on by the first internal voltage Q, the anti-noise unit 115 is in a turn-off state.

Next, during the time period t1 to a time period t2, the operation clock signal OCK1 is transferred from the low level to a high level, the third transistor T3 starts to charge the first control signal GC1, while a boot-strapping effect is generated to the first internal voltage Q by the first capacitor C1. As such, the first internal voltage Q is raised to a higher potential and that the first control signal GC1 may be outputted more completely.

When the first control signal GC1 is at the high level, the gate clock signal GCK6 turns on the eighth transistor T8 and pre-charges the second internal voltage R. At this time, the gate clock signal GCK1 is at the low level, and the ninth transistor T9 is turned on and that the gate signal G1 is pulled down to the low level. At this time, the second control signal PA is still at the low level, and the anti-noise unit 115 is thereby maintained to be in the turn-off state.

During the time period t2 to a time period t3, the gate clock signal GCK1 is transited to the high level, the ninth transistor T9 starts to charge the gate signal G1, while the boot-strapping effect is generated to the second internal voltage R by the third capacitor C3. As such, the second internal voltage R is raised to a higher potential and that the gate signal G1 may be outputted more completely. At this time, the gate signals G3, G5, and G7 are outputted in sequence as well.

During the time period t3 to a time period t4, the first control signal GC1 is transited to the low level, and the gate clock signal GCK6 turns on the eighth transistor T8 again, and the first internal voltage Q is discharged by the third transistor T3. Moreover, the operation clock signal OCK3 turns on the seventh transistor T7 and the eleventh transistor T11, such that the first control signal GC1 and the gate signal G1 are pulled down to the low level. After the time period t4, operation of the gate driver unit 100a is generally completed until the next startup signal, while the anti-noise unit 115 starts to operate, so as to ensure that when the gate driver unit 100a is in a non-operational period, the first internal voltage Q, the first control signal GC1, and the gate signal G1 are not in a floating state.

Similarly, after the first control signal GC1 is enabled, the first control signal GC2 of the next stage is enabled next for providing the subsequent gate signals G9, G11, G13, and G15.

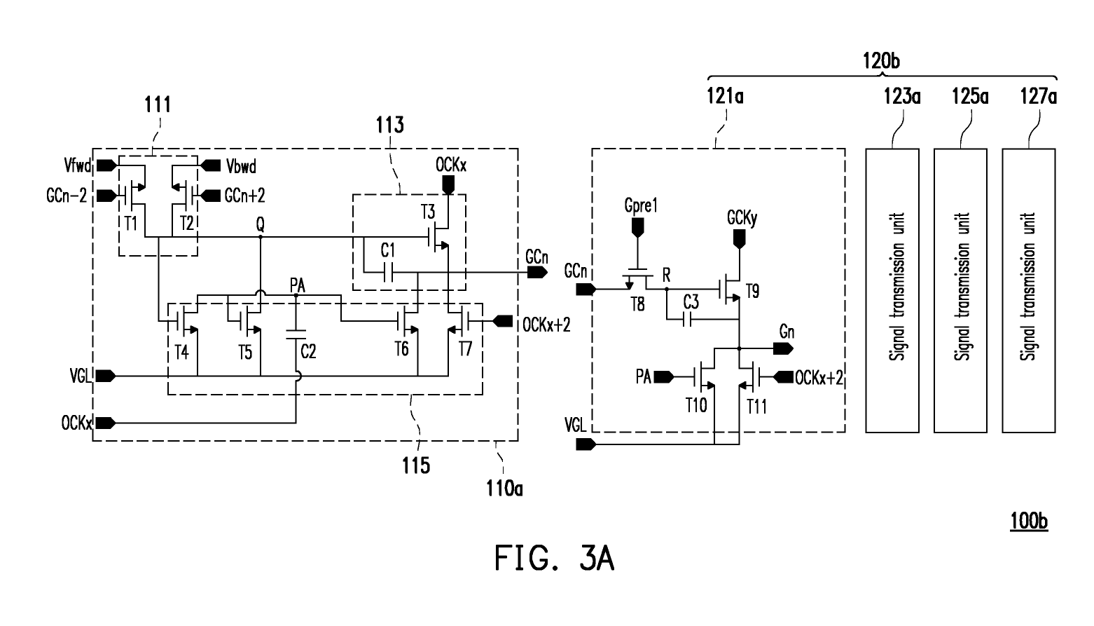

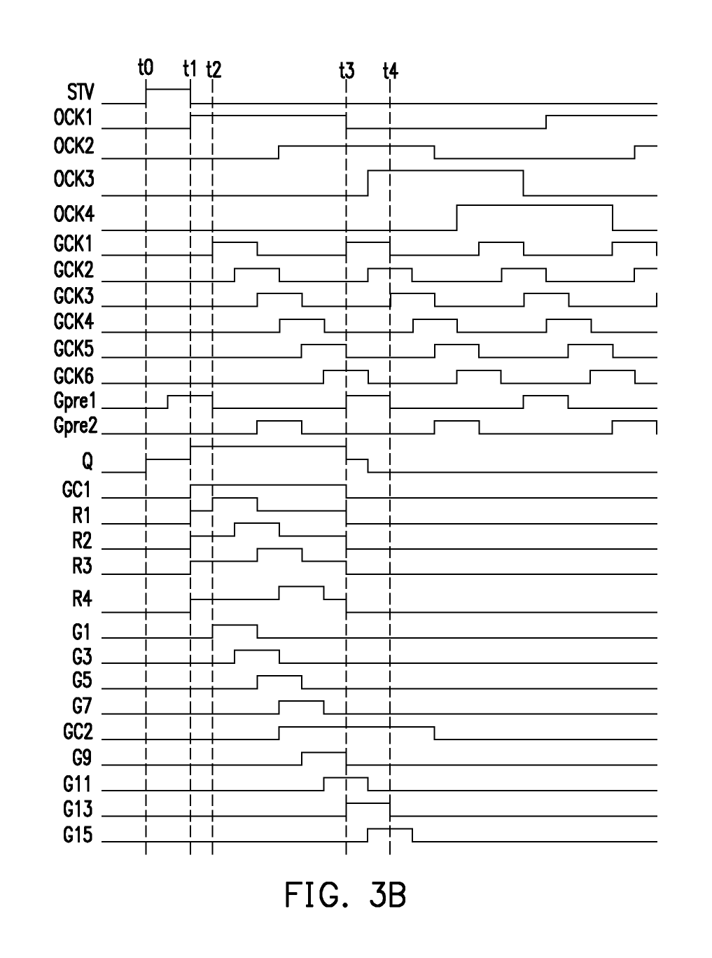

FIG. 3A is a schematic diagram of a circuit of a gate driver unit according to a second embodiment of the invention. With reference to FIG. 2A and FIG. 3A, a gate driver unit 100b is substantially identical to the gate driver unit 100a, and a difference therebetween includes signal transmission units 121a, 123a, 125a, and 127a of a de-multiplexer 120b. Herein, identical or similar components are assigned with identical or similar reference numerals. Comparing between the signal transmission unit 121a and the signal transmission unit 121, the control terminal of the eighth transistor T8 of the signal transmission unit 121a receives a pre-charge clock signal Gpre1, meaning that the control terminal of the eighth transistor T8 of the signal transmission unit 121a receives clock signals other than the operation clock signals OCK1 to OCKi and the gate clock signals GCK1 to GCKj.

FIG. 3B is a schematic diagram of driving waveforms of the gate driver units according to the second embodiment of the invention. With reference to FIG. 2A, FIG. 2B, FIG. 3A, and FIG. 3B, a difference between FIG. 3B and FIG. 2B includes the pre-charge clock signal Gpre1 and a pre-charge clock signal Gpre2. In this embodiment, the pre-charge clock signals Gpre1 and Gpre2 have the same pulse widths but are enabled in sequence, and central points of enabling durations of the pre-charge clock signals Gpre1 and Gpre2 are substantially aligned with rising edges of the operation clock signals OCK1 to OCK4 respectively. Such that, when the first internal voltage Q is at the high level, the eighth transistors T8 in the signal transmission units 121a, 123a, 125a, 127a are thereby turned on, so as to charge the second internal voltages R1 to R4 in the signal transmission units 121a, 123a, 125a, and 127a.

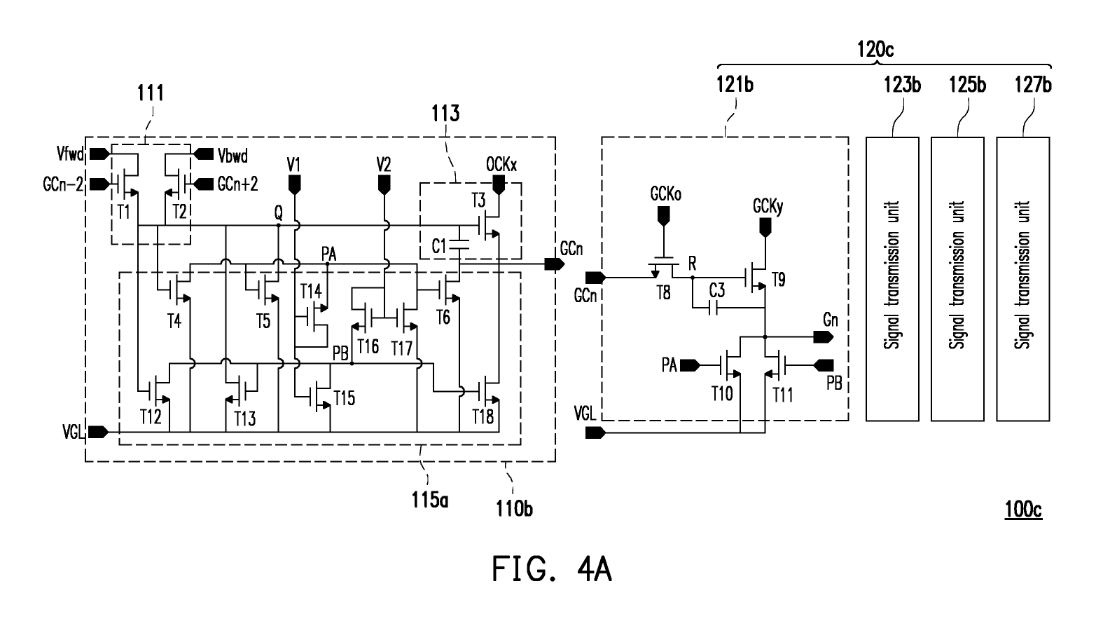

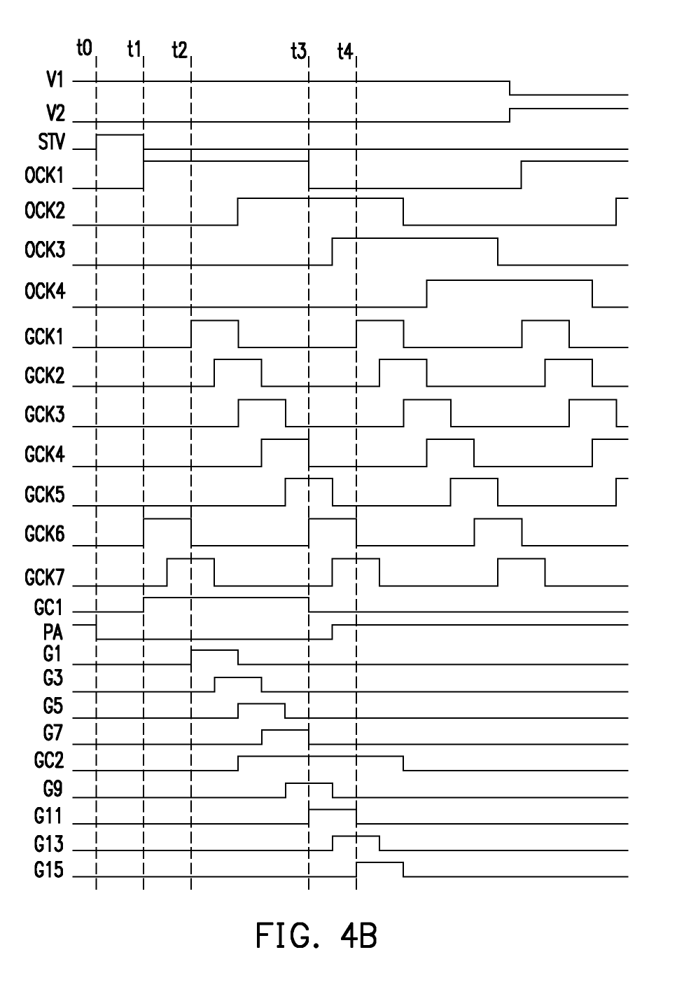

FIG. 4A is a schematic diagram of a circuit of a gate driver unit according to a third embodiment of the invention. With reference to FIG. 2A and FIG. 4A, a gate driver unit 100c is substantially identical to the gate driver unit 100a, wherein identical or similar components are assigned with identical or similar reference numerals. In this embodiment, an anti-noise unit 115a of a shift register 110b further includes a twelfth transistor T12, a thirteenth transistor T13, a fourteenth transistor T14, a fifteenth transistor T15, a sixteenth transistor T16, a seventeenth transistor T17, and an eighteenth transistor T18.

The twelfth transistor T12 has a first terminal receiving a third control signal PB, a control terminal receiving the first internal voltage Q, and a second terminal receiving the gate low voltage VGL. The thirteenth transistor T13 has a first terminal receiving the first internal voltage Q, a control terminal receiving the third control signal PB, and a second terminal receiving the gate low voltage VGL. The fourteenth transistor T14 has a first terminal receiving the second control signal PA, a control terminal receiving a first low frequency signal V1, and a second terminal receiving the first low frequency signal V1. The fifteenth transistor T15 has a first terminal receiving the third control signal PB, a control terminal receiving the first low frequency signal V1, and a second terminal receiving the gate low voltage VGL. The sixteenth transistor T16 has a first terminal receiving a second low frequency signal V2, a control terminal receiving the second low frequency signal V2, and a second terminal receiving the third control signal PB. The seventeenth transistor T17 has a first terminal receiving the second control signal PA, a control terminal receiving the second low frequency signal V2, and a second terminal receiving the gate low voltage VGL. The eighteenth transistor T18 has a first terminal receiving the first control signal GCn, a control terminal receiving the third control signal PB, and a second terminal receiving the gate low voltage VGL.

In signal transmission units 121b, 123b, 125b, and 127b of a de-multiplexer 120c, the control terminal of the eleventh transistor T11 receives the third control signal PB (corresponding to the pull-down control signal) as shown in the signal transmission unit 121b.

FIG. 4B is a schematic diagram of driving waveforms of the gate driver units according to the third embodiment of the invention. With reference to FIG. 2A, FIG. 2B, FIG. 4A, and FIG. 4B, a difference between FIG. 4B and FIG. 2B includes the first low frequency signal V1 and the second low frequency signal V2, wherein the second low frequency signal V2 is opposite to the first low frequency signal V1. When the first internal voltage Q is at the low level, the enabled first low frequency signal V1 raises the second control signal PA and pulls down the third control signal PB. Alternatively, the enabled second low frequency signal V2 raises the third control signal PB and pulls down the second control signal PA. As such, stress of the fifth transistor T5, the sixth transistor T6, the tenth transistor T10, the eleventh transistor T11, the thirteenth transistor T13, and the eighteenth transistor T18 can be suppressed.

In view of the foregoing, in the gate driver circuit of the embodiments of the invention, one shift register corresponds to plural de-multiplexers to control the de-multiplexers to output the gate signals. Moreover, the anti-noise unit in the shift register may ensure that the first internal voltage, the first control signal, and the gate signals are not in the floating state when the gate driver unit is in the non-operational period. Therefore, in the gate driver unit, output stability may be enhanced and erroneous output may be less likely to occur.

What is claimed is:

1. A gate driver circuit, comprises:
a plurality of gate driver units, coupled to each other in sequence, wherein each of the gate driver units comprises:
a shift register, receiving one of a plurality of operation clock signals and a startup signal and generating a first control signal and a second control signal according to the startup signal and the received operation clock signal; and
a de-multiplexer, coupled to the shift register and receiving a portion of a plurality of gate clock signals to output the received portion of the gate clock signals according to the first control signal to generate a plurality of gate signals in sequence, wherein the gate clock signals are enabled in sequence, and enabling durations of two consecutive clock signals in the gate clock signals are partially overlapped.

2. The gate driver circuit as claimed in claim 1, wherein the shift register of each of the gate driver units comprises:
a voltage setting unit, receiving a forward scanning voltage, a backward scanning voltage, the startup signal, and a turn-off signal to set a first internal voltage;
a shift output unit, receiving one of the operation clock signals and the first internal voltage and determining whether to output the received operation clock signal according to the first internal voltage to provide the first control signal; and
an anti-noise unit, receiving the first internal voltage and the first control signal to provide the second control signal according to the first internal voltage and pull down the first control signal according to the first internal voltage.

3. The gate driver circuit as claimed in claim 2, wherein the turn-off signal of each of the gate driver units is the first control signal provided by the gate driver unit two stages later.

4. The gate driver circuit as claimed in claim 2, wherein the de-multiplexer of each of the gate driver units comprises:
a plurality of signal transmission units, respectively receiving one of a portion of continuity gate clock signals in the gate clock signals, the first control signal, and the second control signal, wherein the signal transmission units are turned on simultaneously according to the first control signal, and the signal transmission units respectively provide the received clock signals to respectively generate the gate signals,
wherein the signal transmission units are cut off simultaneously according to the second control signal.

5. The gate driver circuit as claimed in claim 4, wherein the voltage setting unit comprises:
a first transistor, having a first terminal receiving the forward scanning voltage, a control terminal receiving the startup signal, and a second terminal receiving the first internal voltage; and
a second transistor, having a first terminal receiving the backward scanning voltage, a control terminal receiving the turn-off signal, and a second terminal receiving the first internal voltage.

6. The gate driver circuit as claimed in claim 5, wherein the shift output unit comprises:
a third transistor, having a first terminal receiving one of the operation clock signals, a control terminal receiving the first internal voltage, and a second terminal providing the first control signal; and
a first capacitor, coupled between the control terminal of the third transistor and the second terminal of the third transistor.

7. The gate driver circuit as claimed in claim 6, wherein the anti-noise unit comprises:
a fourth transistor, having a first terminal receiving the second control signal, a control terminal receiving the first internal voltage, and a second terminal receiving a gate low voltage;
a fifth transistor, having a first terminal receiving the first internal voltage, a control terminal receiving the second control signal, and a second terminal receiving the gate low voltage; and
a sixth transistor, having a first terminal receiving the first control signal, a control terminal receiving the second control signal, and a second terminal receiving the gate low voltage.

8. The gate driver circuit as claimed in claim 7, wherein the anti-noise unit further comprises a second capacitor coupled between the operation clock signal received by each of the gate driver units and the second control signal.

9. The gate driver circuit as claimed in claim 7, wherein the anti-noise unit further comprises a seventh transistor having a first terminal receiving the first control signal, a control terminal receiving the operation clock signal two stages later of the operation clock signal received by the shift output unit, and a second terminal receiving the gate low voltage.

10. The gate driver circuit as claimed in claim 7, wherein each of the signal transmission units comprises:
an eighth transistor, having a first terminal receiving the first control signal, a control terminal receiving a charge control signal, and a second terminal receiving a second internal voltage;
a ninth transistor, having a first terminal receiving one of the portion of the continuity gate clock signals in the gate clock signals, a control terminal receiving the second internal voltage, and a second terminal providing the corresponding gate signal;
a third capacitor, coupled between the control terminal of the ninth transistor and the second terminal of the ninth transistor;
a tenth transistor, having a first terminal receiving the corresponding gate signal, a control terminal receiving the second control signal, and a second terminal receiving the gate low voltage; and
an eleventh transistor, having a first terminal receiving the corresponding gate signal, a control terminal receiving a pull-down control signal, and a second terminal receiving the gate low voltage.

11. The gate driver circuit as claimed in claim 10, wherein the charge control signal is a pre-charge clock signal.

12. The gate driver circuit as claimed in claim 10, wherein the charge control signal is one of the gate clock signals not received by the de-multiplexer.

13. The gate driver circuit as claimed in claim 10, wherein the pull-down control signal is the operation clock signal two stages later of the operation clock signal received by the shift output unit.

14. The gate driver circuit as claimed in claim 10, wherein the anti-noise unit further comprises:
a twelfth transistor, having a first terminal receiving a third control signal, a control terminal receiving the first internal voltage, and a second terminal receiving the gate low voltage;
a thirteenth transistor, having a first terminal receiving the first internal voltage, a control terminal receiving the third control signal, and a second terminal receiving the gate low voltage;
a fourteenth transistor, having a first terminal receiving the second control signal, a control terminal receiving a first low frequency signal, and a second terminal receiving the first low frequency signal;
a fifteenth transistor, having a first terminal receiving the third control signal, a control terminal receiving the first low frequency signal, and a second terminal receiving the gate low voltage;
a sixteenth transistor, having a first terminal receiving a second low frequency signal, a control terminal receiving the second low frequency signal, and a second terminal receiving the third control signal;
a seventeenth transistor, having a first terminal receiving the second control signal, a control terminal receiving the second low frequency signal, and a second terminal receiving the gate low voltage; and
an eighteenth transistor, having a first terminal receiving the first control signal, a control terminal receiving the third control signal, and a second terminal receiving the gate low voltage.

15. The gate driver circuit as claimed in claim 14, wherein the pull-down control signal is the third control signal.

16. The gate driver circuit as claimed in claim 14, wherein the second low frequency signal is opposite to the first low frequency signal.

17. The gate driver circuit as claimed in claim 1, wherein the first control signal of each of the gate driver units is provided to the gate driver unit two stages later to act as the corresponding startup signal.
